(19) United States
(12) Patent Application Publication
(10) Pub. No.: US 2025/0357038 A1
(43) Pub. Date: Nov. 20, 2025

(54) CURRENT SENSING TRANSFORMERS WITH HYBRID MATERIAL

(71) Applicant: Atlas Magnetics, Reno, NV (US)

(72) Inventor: John Othniel McDonald, Bentonville, AR (US)

(21) Appl. No.: 19/283,001

(22) Filed: Jul. 28, 2025

Related U.S. Application Data
(63) Continuation-in-part of application No. 18/135,660, filed on Apr. 17, 2023, now Pat. No. 12,428,747.
(63) Continuation-in-part of application No. 18/131,350, filed on Apr. 5, 2023.
(60) Provisional application No. 63/677,039, filed on Jul. 30, 2024.

(51) Int. Cl. H01F 27/255; G01R 19/00; H01F 3/10; H01F 17/00; H01F 17/06; H01F 27/28

(52) U.S. Cl. CPC H01F 27/255; G01R 19/0092; H01F 17/0033; H01F 17/062; H01F 27/2823; H01F 2003/106

(57) ABSTRACT

Utilizing hybrid materials in a current sensing transformer with primary to secondary coil ratios greater than one is possible and practical. The ease of manufacture associated with this method allows almost any inductor of any size to be converted into a current sensing transformer without significantly increasing the size, cost, or time of manufacture or affecting the performance of the inductor itself. The result is low-cost, high-performance AC and DC current sense components.

### FIELD OF INVENTION

The present disclosure relates to current sensing transformers, and more particularly to a current sensing transformer incorporating hybrid materials for improved performance and compact size.

### BACKGROUND

It is well known in the art that current can be sensed in a system by utilizing the magnetic field it creates. In general, this is achieved in alternating current systems by using the magnetic field to induce voltage or current in another system. In contrast, in direct current sensing systems, a voltage can be induced in another system by using a sensor such as a Hall Effect or simple resistor.

Each method of inductive current sensing that is used today has its own drawbacks and benefits. For example, here, we will focus on transformer-based current sensors, which are traditionally more expensive and physically larger as compared to resistive sensor solutions commonly in high-volume production. The known cutting-edge 7A current sense transformers, at the time of writing, are limited to around twenty square millimeters in size. As such, the current sensing transformers utilized in many systems today tend to be a larger component in an electrical system.

It will be appreciated that coil ratios tend to serve as a size limiter for the current sensing transformers. Even keeping the same ratio but merely increasing the primary windings has a huge effect on current sensing transformer size; for example, expand primary windings from 1 to 5 on a current transformer that has to have a 1:40 primary to secondary coil ratio, and you require 200 windings for the secondary coils.

Current sensing transformers often have ratios of secondary to primary windings greater than 1. It is easy to see why when looking at a current-sensing transformer. For example, a toroidal current sensing transformer may comprise a toroidal inductor serving as the secondary windings and a primary wire passing through the center of the toroid. This design inherently results in a high ratio of primary windings to secondary windings. These ratios are often in the range of 1:10 to 1:1000 (primary:secondary), and the higher the ratio, the more accurate the current measurement.

However, it should be noted that at high frequencies, issues arise in high winding ratio current sense transformers with self-inductance, magnetic saturation, and leaked inductance.

A lower ratio of primary windings to secondary windings would help keep these negative effects down, as well as keep the current sensing transformer from reaching magnetic flux saturation too early at high currents. Yet, these lower ratios also have their downsides, as they tend to distort signals and be unstable.

These considerations require careful balancing when designing a current sensing transformer. Yet, there is a strong need for smaller current sensing transformers. In theory, it would be appreciated if a smaller sensing transformer could have a variety of uses. It can be useful to the manufacture of magnetic devices to measure flux in an area, for example, a core; it is useful to the designer of electronic systems to measure the current in the given area; and it is useful for the creation of electronic devices to have a system that can sense signals (for example to sense a signal triggered by an on/off switch).

The manufacture of magnetic components for circuits will often require measuring the magnetic flux generated by their components. For example, the manufacturer provides an inductor with a core and wishes to sense how much magnetic flux is in the core to check its performance.

A designer of electronic systems will often need to know the level of current flowing through the system. It is very useful to the system designer to understand the current within the system without significantly interrupting or altering the performance of the system itself.

A designer of consumer electronics will often incorporate systems into the device that only turn on when current is sensed in another system. For example, there is a system that is always on in most modern phones connected to the power button (without power, a modern power button would not work). In these cases, the power button does not operate as a switch, instead it sends a signal. It is important that that signal be sensed to awaken the rest of the device.

From these examples, it can be seen that there is a need to enable small current sensors which do not leak magnetic fields and do not significantly increase the cost of the current transformers. As current sensing transformers become more prevalent, designers will have more flexibility in their designs.

### SUMMARY

This summary is provided to introduce a selection of concepts in a simplified form that are further described below in the detailed description. This summary is not intended to identify key features or essential features of the claimed subject matter, nor is it intended to be used as an aid in determining the scope of the claimed subject matter.

Presented herein is a method and apparatus for sensing flux, current, and signals, which can be integrated into semiconductor packaging or presented as a separately mounted solution. The result is an inductive current sensor that enables ratios of primary to secondary windings of one or greater than one.

This is achieved by the presence of hybrid materials, which are able to shrink conductors and magnetic cores while maintaining high performance. The small size and high-frequency capabilities of these parts allow for novel forms of sensors and unlock new integrations for sensors or at least reduce negative side effects that would incur if other solutions were integrated into their place.

These materials are used to reduce the size of inductors over bulk materials while maintaining high accuracy and stability. This allows for significantly fewer windings to be used when hybrid materials have been incorporated into the system.

When the hybrid materials are applied to current sensing transformers, the primary, secondary, and core may be reduced in size. However, more than that, by using a hybrid material for the sensing coil, the sensing coil may retain a winding ratio with the primary coil of greater than 1. So, for example, for every 100 primary windings, there is one secondary winding.

It is worth noting that inductors created by hybrid materials are suitable for integration into the smallest of electrical systems. The present invention converts these inductors and even non-hybrid inductors into primary windings without significantly increasing the size or adding to the cost of manufacturing.

As a result, an exemplary embodiment is a current sensing inductor that has a primary coil, a secondary coil, and a core, wherein the coils are operably positioned in relation to the core, and at least one of the primary coils or one of the secondary coils incorporates a hybrid material.

Having at least one hybrid material component improves the performance of the transformer and allows it to shrink in size. When the secondary coil is a hybrid material, it may be reduced to one winding or coil. This allows the ratio of the primary coils to the secondary coils to be greater than 1. It is worth noting that a secondary coil may have more than one winding, and the transformer still has a ratio of primary to secondary coils greater than 1. It is also worth noting that alternate embodiments with a primary to secondary coil winding ratio less than 1 are very possible.

These windings may be applied to a variety of core types, including shell type and “core” type cores. When the core has at least two legs the primary and secondary coils may be put on separate legs. However, this is not necessary, and it may be more efficient to manufacture a secondary and primary coil on the same leg.

When it comes to core-type cores, for example, a toroidal core, there is essentially one leg, and therefore, the primary and secondary coils are on the same leg. When on the same leg in both core and shell-type cores, the secondary coil may be arranged as a helix: for example, a primary and secondary coil may form a double helix, while two secondary coils and one primary form a triple helix, and so forth.

This brings up the fact that there may be at least two secondary coils. In such cases, the coils may but need not be identical, nor do they need to be on the same leg of the core when more than one leg is present. For example, a longer coil could be used for more sensitive applications, while the smaller coil could be used for less sensitive applications. A secondary coil may be placed on each of the outside legs of the core while the center legs hold the primary coil.

It will also be appreciated herein that the number of primary and secondary coils is not inherently ratio-driven. The performance of a hybrid single secondary winding is strong enough to cover a wide range of primary windings over a wide range of currents and frequencies to the degree that, in many cases, the turn ratio may be practically ignored. However, certain ratios may be utilized.

These current senses can be operably connected to an LC tank Circuit or other oscillator to create an AC and DC current sense. Groupings of these current senses can be placed on a single die. When each has a different size, this can allow for accurate current sense over a range of frequencies.

Because the hybrid materials that make up the core can be made in a variety of sizes, they can also serve as flux concentrators for Hall-effect sensors. They are powerful enough to significantly reduce the size of the Hall-effect sensors and enable them to be packaged on a die for a low cost.

According to an aspect of the present disclosure, a current sensing transformer is provided. The current sensing transformer includes a primary coil, a secondary coil, and a substrate-layered magnetic core. The primary coil and the secondary coil are operably positioned in relation to the substrate-layered magnetic core. At least one of the primary coil or the secondary coil incorporates a hybrid material.

According to an aspect of the present disclosure, a current sensing transformer is provided. The current sensing transformer includes a primary coil, a secondary coil, and a substrate-layered magnetic core. The primary coil and the secondary coil are operably positioned in relation to the substrate-layered magnetic core. At least one of the primary coil or the secondary coil incorporates a hybrid material.

According to other aspects of the present disclosure, the current sensing transformer may include one or more of the following features. The substrate-layered magnetic core may comprise a hybrid material. A ratio of primary coil windings to secondary coil windings may be greater than 1. The secondary coil may comprise a single winding. The current sensing transformer may further comprise an LC tank circuit electrically connected to the secondary coil. The LC tank circuit may enable sensing of both AC and DC currents. The current sensing transformer may be integrated into semiconductor packaging.

According to another aspect of the present disclosure, a method of forming a current sensing transformer is provided. The method includes forming a primary coil, forming a secondary coil, forming a substrate-layered magnetic core, and operably positioning the primary coil and the secondary coil in relation to the substrate-layered magnetic core.

According to other aspects of the present disclosure, the method may include one or more of the following features. Forming the substrate-layered magnetic core may comprise incorporating a hybrid material into the substrate-layered magnetic core. The method may further comprise forming the primary coil and the secondary coil such that a ratio of primary coil windings to secondary coil windings is greater than 1. Forming the secondary coil may comprise forming a single winding. The method may further comprise electrically connecting an LC tank circuit to the secondary coil. The LC tank circuit may enable sensing of both AC and DC currents. The method may further comprise integrating the current sensing transformer into semiconductor packaging.

According to another aspect of the present disclosure, a current sensing system is provided. The current sensing system includes a current sensing transformer having a primary coil, a secondary coil, and a substrate-layered magnetic core. The primary coil and the secondary coil are operably positioned in relation to the substrate-layered magnetic core, and at least one of the primary coil or the secondary coil incorporates a hybrid material. The current sensing system also includes an LC tank circuit operably connected to the secondary coil.

According to other aspects of the present disclosure, the current sensing system may include one or more of the following features. The substrate-layered magnetic core may comprise a hybrid material. A ratio of primary coil windings to secondary coil windings may be greater than 1. The secondary coil may comprise a single winding. The LC tank circuit may enable sensing of both AC and DC currents. The current sensing system may be integrated into semiconductor packaging.

The foregoing general description of the illustrative embodiments and the following detailed description thereof are merely exemplary aspects of the teachings of this disclosure and are not restrictive.

### BRIEF DESCRIPTION OF THE FIGURES

FIG. 1 shows a secondary coil sharing a core with a primary coil, the secondary coil placed between loops of the primary coil.

FIG. 2 shows a secondary coil sharing a core with a primary coil, the secondary coil placed on a different leg of the core than the primary core.

FIG. 3 shows a secondary coil with a thinner return wire.

FIG. 4 shows a potential pathway for a secondary coil with a shell-type core.

FIG. 5 shows a potential pathway for a secondary coil with a shell-type core.

FIG. 6 shows a potential pathway for a secondary coil with a shell-type core.

FIG. 7 shows complex potential pathways for a secondary coil with a shell-type core.

FIG. 8 shows a potential placement for secondary coils when using multiple coils.

FIG. 9 shows a solution for fitting a secondary coil onto the center leg of a core by allowing the primary coil to travel up and around a secondary coil.

FIG. 10 shows a current sense with more secondary than primary coils using the elevated lift method of FIG. 9.

FIG. 11 shows a primary and secondary coil in a double helix configuration.

FIG. 12 shows a secondary coil placement on a simple “core type” core.

FIG. 13 shows a partial double helix configuration on a “core type” core.

FIG. 14 shows an alternate potential partial double helix configuration on a “core type” core.

FIG. 15 shows a simple secondary coil configuration on a toroidal core.

FIG. 16 shows a simple secondary coil configuration with multiple loops on a toroidal core.

FIG. 17 shows a current sense having a secondary winding operably connected to an LC Tank circuit.

FIG. 18 shows a potential B-H curve for the device of FIG. 17.

FIG. 19 shows multiple current senses on a single die and operably connected to each other.

FIG. 20 shows multiple B-H curves for the devices shown in FIG. 19.

### DETAILED DESCRIPTION

The present invention relates to the sensing of magnetic flux in electrical systems. It allows for the conversion of inductors into current sensing transformers without significantly increasing the size of the inductor or the cost of manufacture.

Hybrid materials, which have thin layers of insulation that the primary layers may pierce and connect through, have enabled the manufacture of small high-frequency magnetics at practical costs for their incorporation into consumer electronic devices. Inductors with hybrid materials windings or cores offer high performance and can bring this performance to many systems.

It is worth noting that a hybrid material with insulation layers may best pictured as a single, solid piece of metal built up one ultra-thin layer at a time. After each metallic layer is deposited, a very thin, intentionally porous insulation layer is laid on top; the insulation layer covers almost all the surface but leaves microscopic pinholes. When the next metallic layer is deposited, metal grows down through those pinholes and welds itself to the layer below, so the entire stack turns into one continuous conductor. The finished structure behaves electrically like a bulk metal bar, yet the embedded porous insulation interrupts eddy currents and tailor skin-depth in ways that ordinary laminates cannot.

Stated more formally, in at least one embodiment of the present invention a Hybrid Material—as used herein, denotes a monolithic conductive body formed by the successive deposition of (i) an electrically conductive metallic stratum and (ii) a deliberately porous electrically insulating stratum in such a way that, during deposition of the next metallic stratum, metal penetrates the porosity and metallurgically bonds to the underlying conductor across substantially the entire interfacial area. The resulting body behaves electrically as a single conductor characterised by a unitary skin-depth and a strongly anisotropic (direction-dependent) impedance profile. Because continuity between conductive strata is created in situ through the pores of the insulating stratum, the process can be completed without a subsequent step—such as drilling, laser-ablating, etching or photo-patterning—to open discrete holes or vias. In fact, any structure that attains interlayer conductivity only by post-deposition apertures constitutes a laminate and is expressly excluded from this definition in this application.

It is also possible to form a hybrid material with a heterogeneous mixture of a base material, by forming the base material of the hybrid magnetic material while also depositing the hybrid insulation. The result is particles of hybrid insulation which are interspersed, often randomly, throughout the base material, serving as miniature hybrid insulation layers.

Further, in at least one embodiment of the present invention, a hybrid insulation layer—designates the specific porous dielectric strata that appear within a hybrid material. Each layer (a) possesses a bulk resistivity of at least 500 μΩ·cm (e.g., SiO₂, Al₂O₃ or ZrO₂); (b) is 10 nm to 5 μm thick, preferably 30-250 nm when deposited by AP-PECVD or combustion CVD; (c) covers 90-99.99% of the underlying metal while leaving a statistically distributed network of through-voids (e.g., pores) having individual lateral dimensions <40 μm and an overall open-area fraction of 0.01-10%; and (d) is sufficiently permeable that the underlying metal can act directly as the electrode (or catalyst) for depositing the next metallic stratum without seed activation, drilling or via formation. Once back-filled with metal the layer becomes mechanically interlocked with adjoining conductors and cannot be peeled away as a discrete film, further distinguishing it from the dense dielectric sheets used in traditional laminates.

Hybrid cores have high permeability, which provides an excellent signal-to-noise ratio. As a high-frequency material, they can provide a more accurate current sense. Their performance significantly benefits alternating current (AC) sense applications. However, when combined with the low cost of manufacturing hybrid cores, this performance also opens up the door to elegant AC and direct current (DC) inductive sense applications. Given their performance, these cores also open up low-cost, small, substrate-compatible high-performance flux concentrators that allow for small hall effect sensors. First, we will discuss the AC current sense applications, we will then discuss how these inventive components can be used to build inductive AC and DC sense systems and how they can open up smaller hall effect sensors.

It is worth noting that the location these sense components can be placed in is novel for their cost, size, and performance. They can be placed in semiconductor substrates and are compatible with build-up films, for example, Ajinomoto build-up film.

To measure the flux running in hybrid-based or other high-performance systems, it is beneficial to utilize small, sensitive, and accurate sensors that can handle and measure the high performance of these systems.

To achieve these sensors, in an AC system a sensing coil may be added around the core of an inductor. This would act as a current-sensing transformer to ensure a small size. The sensing coil may be a hybrid material. This method would not significantly add to the size of the inductor already in use, and it can be incorporated onto a die or otherwise incorporated into semiconductor packaging

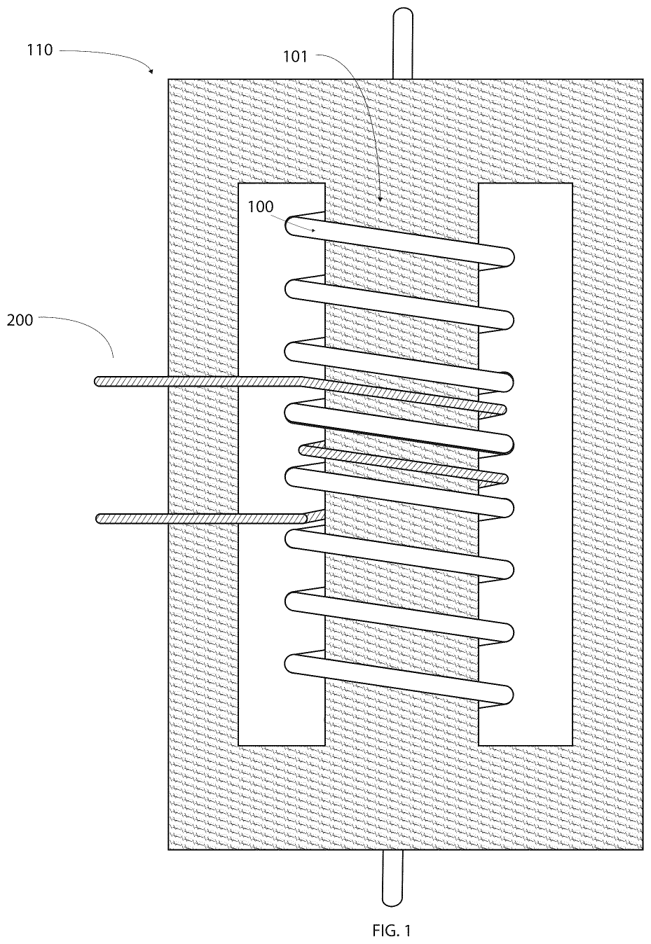

An example of the two coils is shown in FIG. 1. In this figure, the primary coil 100 of an inductor is wound around the center leg 101 of an E-shaped core 110. Between two of the coils of the primary winding 100, there is a smaller secondary coil, 200. The secondary coil 200 shown here is smaller than the primary coil 100. In some cases, a primary coil may be removed to make space from the secondary coil.

It may immediately stand out that the ratio of coils in the primary and secondary wires is flipped from the industry standard of more secondary windings than primary. However, the use of accurate, high-permeability hybrid materials allows this to occur regardless of the core type (allowing hybrid substrate cores to improve performance).

Thus it can be said that the current sensing transformer may comprise a primary coil, a secondary coil, and a substrate-layered magnetic core. In some cases, the primary coil and the secondary coil may be operably positioned in relation to the substrate-layered magnetic core. The current sensing transformer may be used to measure electrical current flowing through the primary coil by detecting changes in the magnetic field induced by the current.

In some implementations, at least one of the primary coil or the secondary coil may incorporate a hybrid material. The hybrid material may enable the fabrication of smaller coils while maintaining high performance characteristics. The use of hybrid materials in the coil construction may allow for a reduction in the number of windings required, particularly for the secondary coil.

The substrate-layered magnetic core may provide a path for the magnetic flux generated by current flowing through the primary coil. In some cases, the substrate-layered magnetic core may also incorporate a hybrid material, which may enhance the magnetic properties of the core while allowing for a compact design.

The compact size and high-performance characteristics of the current sensing transformer may make the transformer suitable for integration into semiconductor packaging. This integration may allow for the incorporation of current sensing capabilities directly into integrated circuits or other semiconductor devices, potentially reducing overall system size and improving performance in various electronic applications.

As noted above, this arrangement of coils allows the current sensing component to be built without significantly affecting the size or cost of the inductor. It has effectively converted the inductor into a current-sensing transformer. Of course, in an alternate embodiment, the secondary coil may also be placed at any point along the core, including at the end of the inductor.

It can easily be appreciated that the two coils can be formed at the same time and of the same material and thus not significantly increase the cost of manufacturing the current sensing transformer over the cost of the inductor. Because a single secondary winding may account for many inductor windings, there is not usually a need to adjust the number of secondary windings.

There are many different types of cores, and although the secondary coils can be placed anywhere on the core, there are some variables which should be taken into account when deciding on where to place the coils.

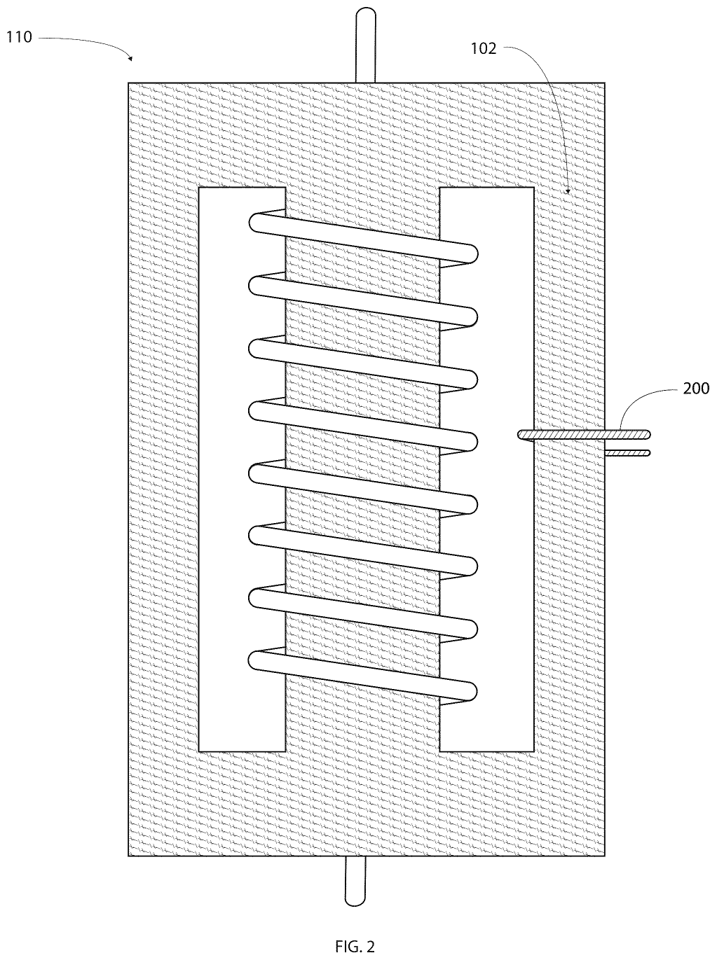

In a “shell type” core, the secondary coil may be placed on any leg of the core. The magnetic flux can be calculated based on where the sensing coil is placed. In FIG. 2 the sensing coil 200 is placed on leg 102 of the core 110 without any other coil around it. The flux running through this leg will be 50% of the total flux in the system. So, here, the sensor would pick up 50% percent of the flux in the core.

It will be appreciated that placing an additional sensor winding around the other core leg (leg 103) in the situation shown in FIG. 2 would allow for an average flux to be taken. It is worth stating that the center leg 101 will effectively have 100% of the flux flowing through it while each of the end legs will have 50% of the total flux.

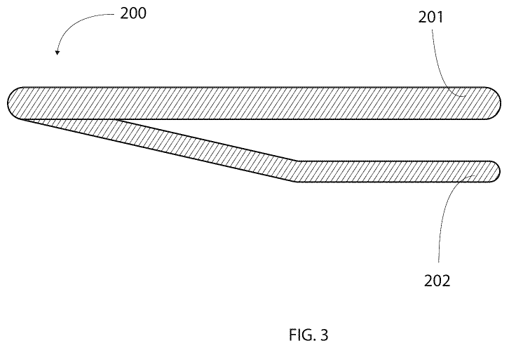

As noted above, in many cases the secondary coil has a single winding, but it need not be limited to a single winding. In some cases, the secondary coil 200 may be configured with different widths for different portions of the coil. FIG. 3 illustrates an exemplary configuration of the secondary coil 200 comprising an outgoing portion 201 and a return portion 202. The outgoing portion 201 may have a larger width compared to the return portion 202. This configuration may allow for optimization of the secondary coil 200 performance while minimizing material usage.

The placement of the secondary coil is worth considering in more detail in relation to how it enters the center leg of a shell-type core. As noted above the center of the core will effectively contain 100% of the flux, while each outer leg will contain 50%. How the secondary core enters into the center leg, when placed on the center leg, will control how the flux in each leg is added.

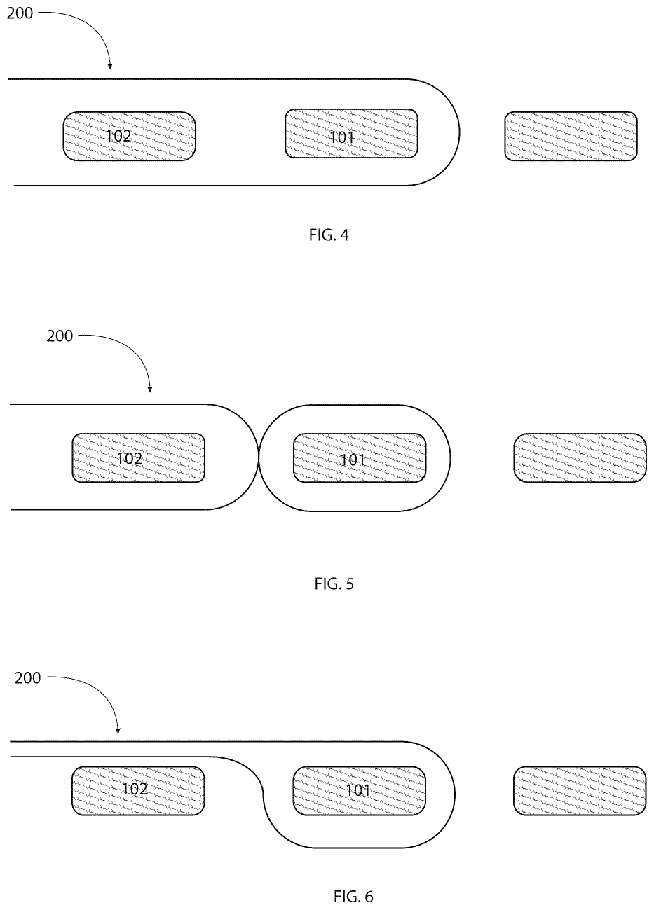

In a case shown in FIG. 4, the secondary coil 200 is looped around the center leg 101 and an outer leg 102 of the core. This configuration results in a secondary coil reading 50% of the total flux in a system. Effectively, what happens here is that the flux of one of the legs is subtracted from the other.

In the case shown in FIG. 5, the secondary coil is wound around the center leg 101 and outer leg 102. However, the loop intersects between the two legs to form two different loops. This configuration adds the flux together so that the total flux sensed by the secondary coil 200 is 150% of the total flux in the system.

In the case shown in FIG. 6, the secondary coil is only looped around the center leg 101 of the core. This results in a secondary coil that only reads the center leg. Thus, the flux recorded will be 100% of the flux.

Of course, these basic looping principles may be expanded upon to create a variety of loop designs as needed to optimize a system. There are a variety of ways to incorporate secondary coils into a core. One reason someone might use these looping schemes is that they have some design constraint with the secondary coil that controls how it exits the core. Several looping schemes are explained below.

In some cases, the secondary coil 200 may be arranged in a first loop configuration 701. The first loop configuration 701 may result in a flux reading of 200% of the system flux. This configuration may provide enhanced sensitivity for detecting small changes in the magnetic field generated by the primary coil 100.

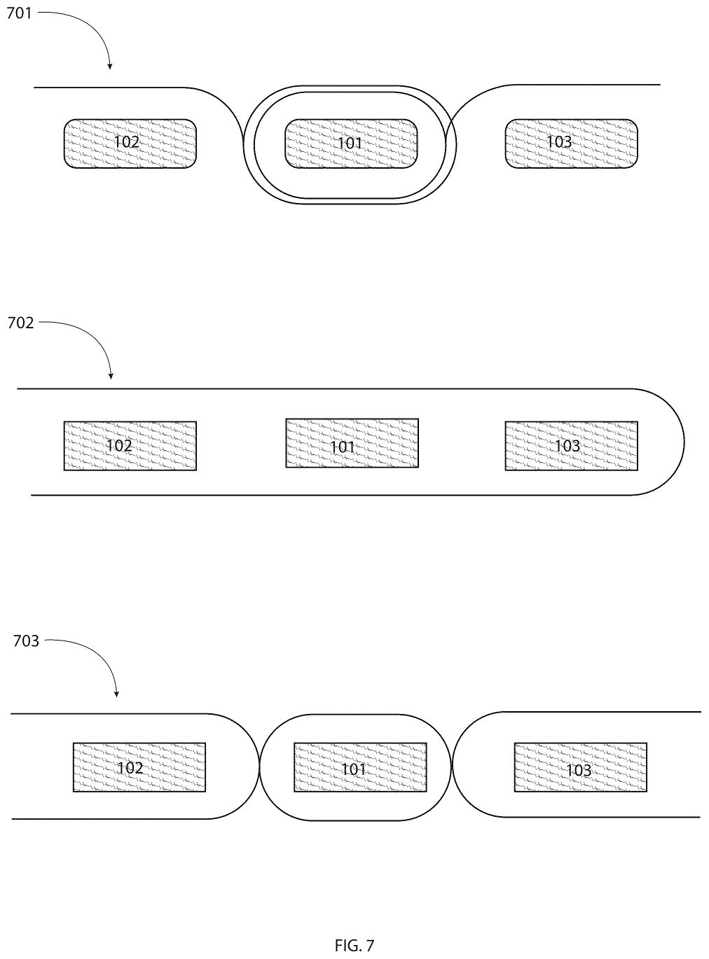

FIG. 7 also depicts a second loop configuration 702 for the secondary coil 200. The second loop configuration 702 may produce a flux reading equivalent to 0% of the system flux. This arrangement may be useful in applications where cancellation of certain flux components is desired.

Additionally, FIG. 7 shows a third loop configuration 703 for the secondary coil 200. The third loop configuration 703 may yield a flux reading of 200% of the system flux, similar to the first loop configuration 701. However, the path of the secondary coil 200 in the third loop configuration 703 may differ from that of the first loop configuration 701, potentially offering advantages in terms of manufacturing or spatial constraints.

As noted above, The choice of loop configuration for the secondary coil 200 may depend on factors such as the desired flux measurement accuracy, spatial limitations within the current sensing transformer, and specific application requirements.

Two or more secondary coils may also be used. When multiple coils are used they sense the flux independently of each other. Because of this. when two or more secondary coils are used, it is possible to, and in some cases, beneficial to have one longer secondary coil. This longer secondary coil will be more sensitive and can be suitable for detecting smaller signals while the short secondary coil handles larger signals.

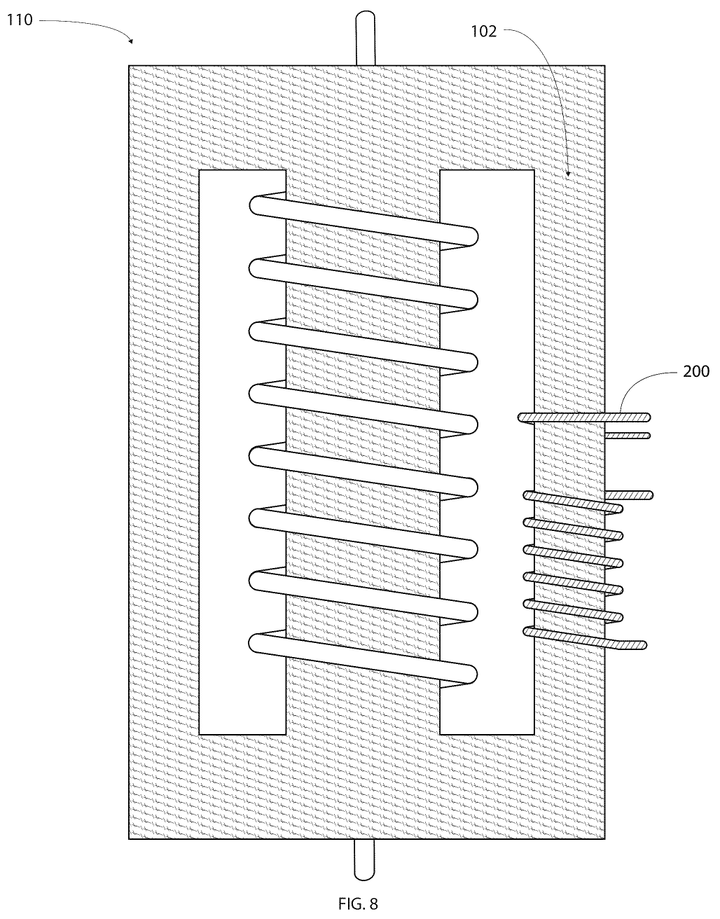

It is worth noting that multiple secondary coils may be placed on the same leg as each other or even on the main leg with the primary coils. FIG. 8 shows an example of two secondary coils 200 and 210 placed on the same core leg, here leg 102. Thus, the incorporation of multiple secondary coils with different configurations or lengths may enable the current sensing transformer to operate effectively across a wider range of current levels or frequencies. This versatility may be particularly beneficial in applications where the current being measured may vary significantly over time or under different operating conditions.

Even in such case, these sensing coils need not significantly affect the size of the inductor system. It is good to remember that these coils are typically smaller than the primary coils and thus generally the core itself will be the size limiting feature of the design.

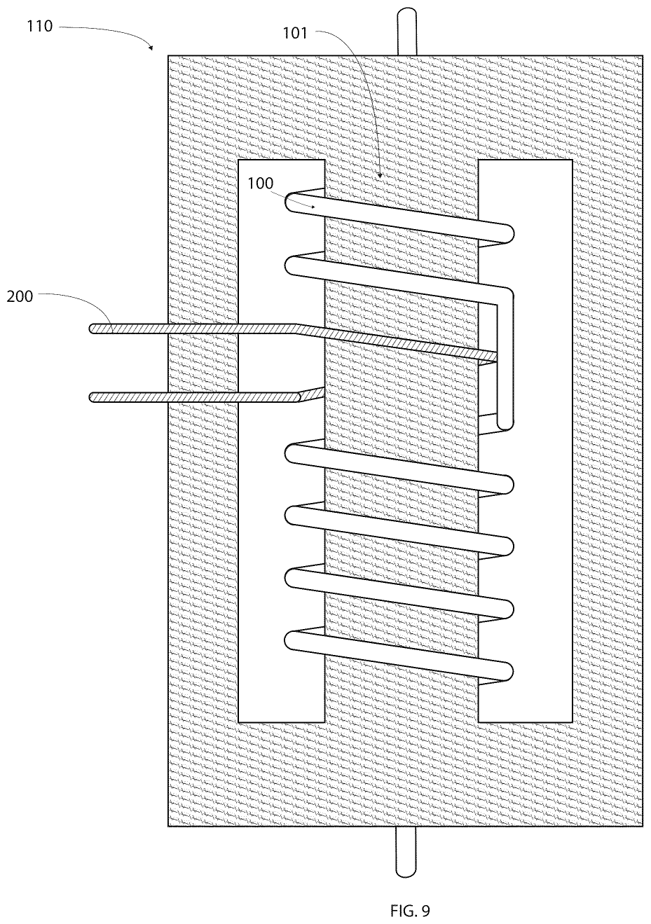

However, to integrate the coils in between the primary coils, the primary coil may be adjusted. FIG. 1 shows the primary coil 100 with a winding going around the center leg 101 so that it does not cross the secondary coil. Another method to allow the secondary coil to sit between the primary coils is to merely stop the winding, go up a layer, cross over the secondary wire, and then drop back down to continue the windings. This is shown in FIG. 9 wherein the primary coil 100 has a crossover connection 104 which connects the primary windings across the secondary coil.

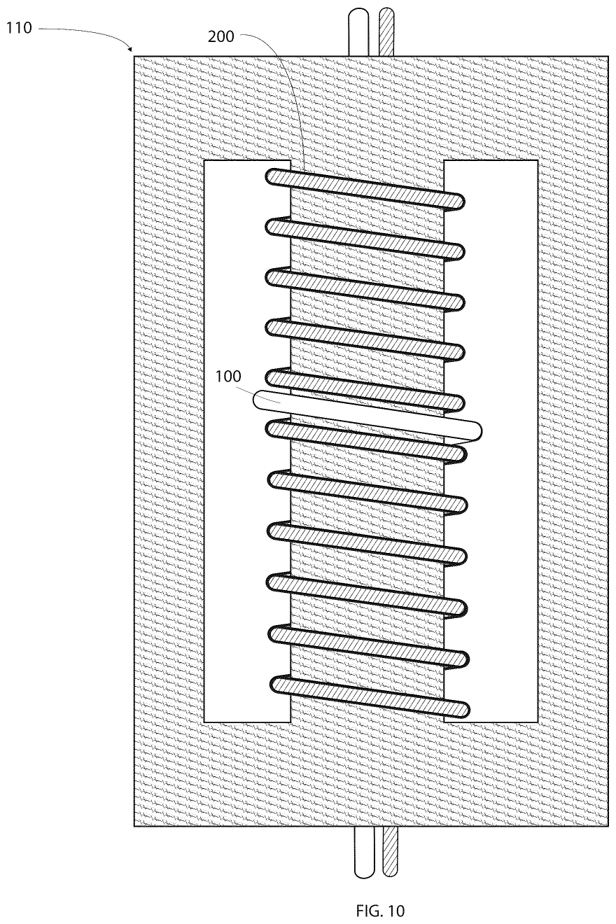

The arrangement shown in FIG. 9 is beneficial for high-voltage systems. However, in low-voltage systems, it may still be beneficial to have more primary coil turns than secondary coil turns. This is shown in FIG. 10, where the primary coil 100 has only one turn while the secondary coil has one turn.

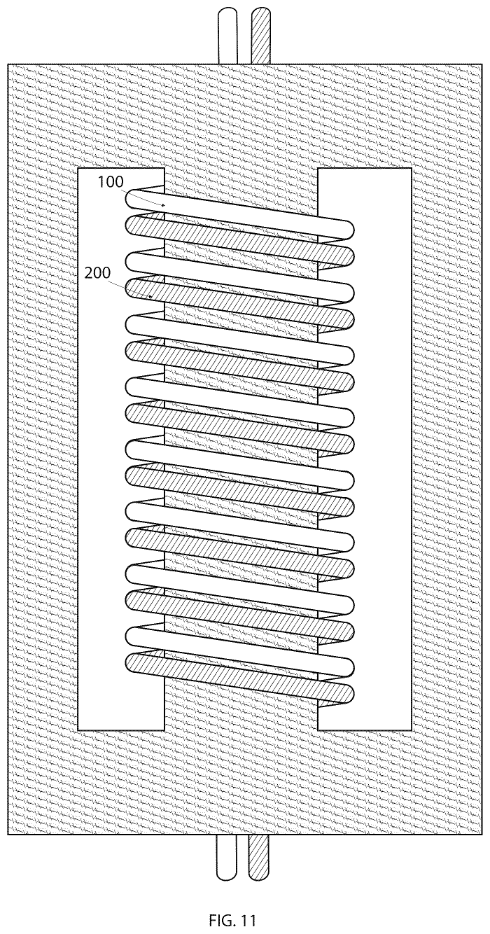

It will be appreciated that the methods of primary winding work for advanced primary coil windings including double helixes. In fact, in an embodiment, the secondary coil may be arranged in a helix configuration in relation to the primary windings forming a double helix. This is shown in FIG. 11 wherein the secondary coil 200 now serves to form a double helix with the primary coil 100 for a portion of the primary coil 100. In fact, many helices can be formed, including triple or greater helices and even partial helixes.

It will be appreciated that with the present invention it is possible to convert any shell-type inductor into a current sensing transformer of the present invention without significantly increasing the size or cost of manufacturing the inductor. This includes planar-type inductors which often have shell-type cores as well as multilayer inductors.

The primary and secondary coils may be plated simultaneously, and this helps reduce the cost of manufacturing.

Unlike the classic image of the transformer with a shell-type core, the primary coil and the secondary coils need not be wound on the outer legs. In fact, in the present invention, the sensing coils do not even need to be wound on the legs but may wind around any part of the core.

It can be appreciated that the present invention also applies to inductors with “core type” cores. A core-type core will typically not have the legs of the shell-type core. This limit means that the secondary coil will be placed either in between two windings of the primary coil or at the ends of the core.

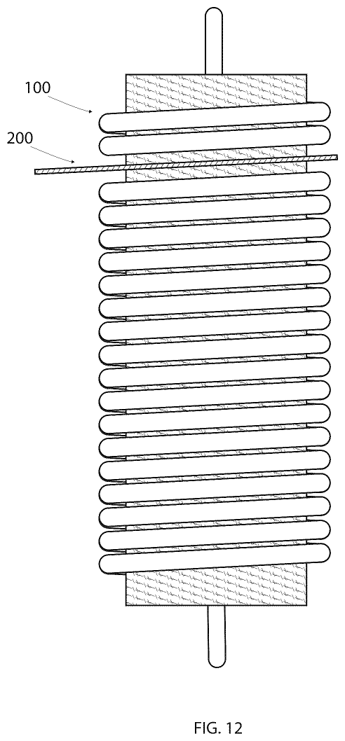

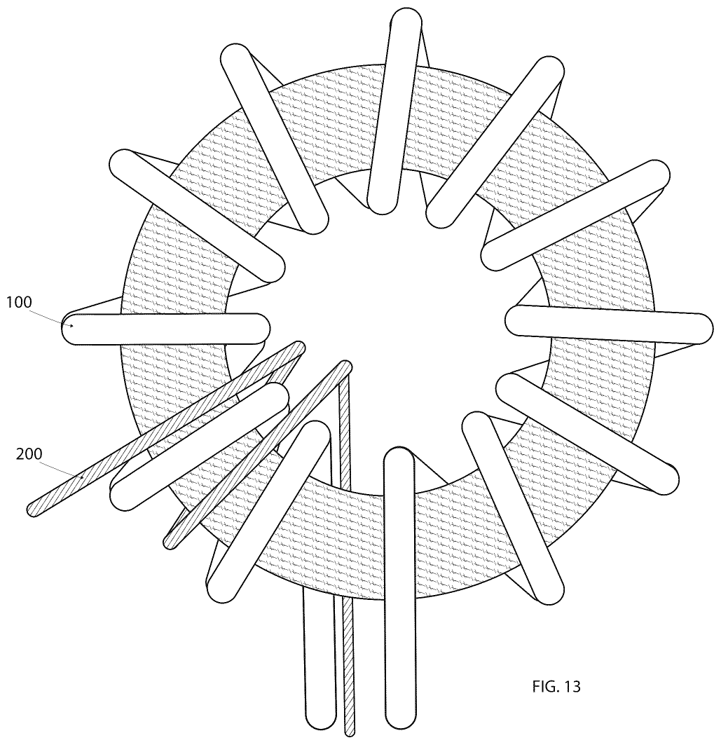

FIG. 12 shows a primary coil 100 around a simple bead core. A secondary coil 200 sits between two coils of the primary coil. Here the core effectively acts like a center leg of the shell-type core and the same general principles apply.

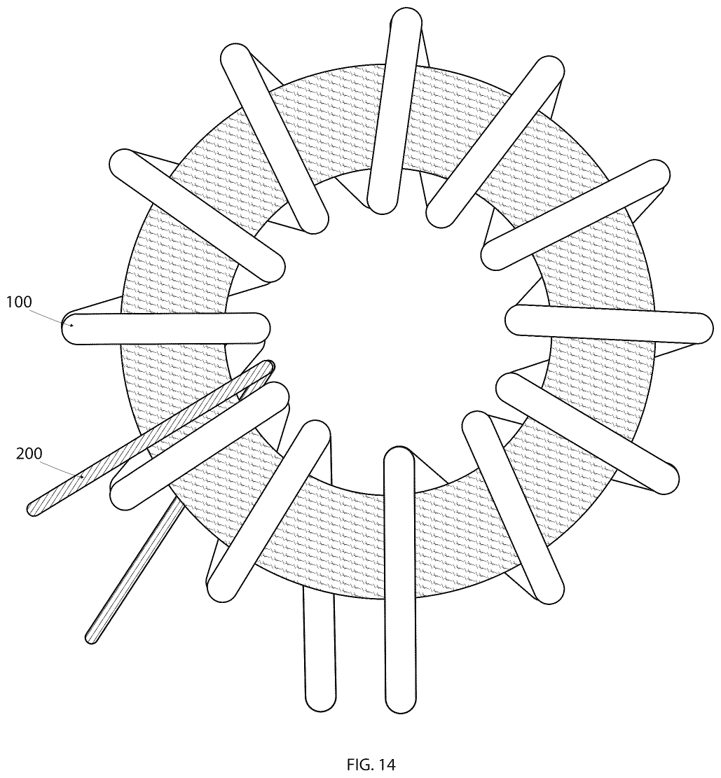

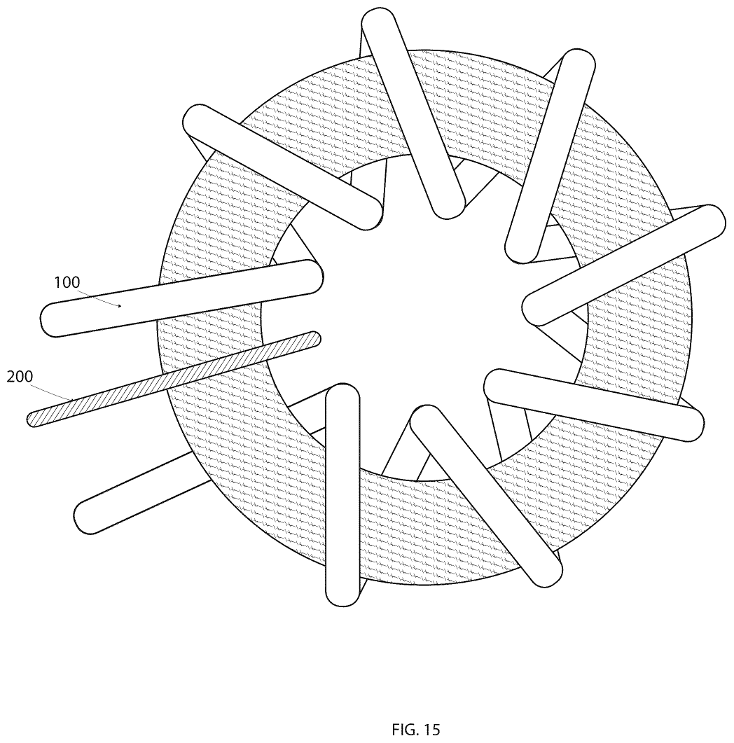

This holds true of most core-type cores, for example a toroid, shown in FIG. 13. Here, the toroid has a primary winding and a secondary winding. The secondary winding is positioned as a partial double helix. This partial double helix may comprise a single loop. However, alternative embodiments may include a single coil not in a double helix configuration, an example shown in FIG. 14, or a series of loops, an example is shown in FIG. 13.

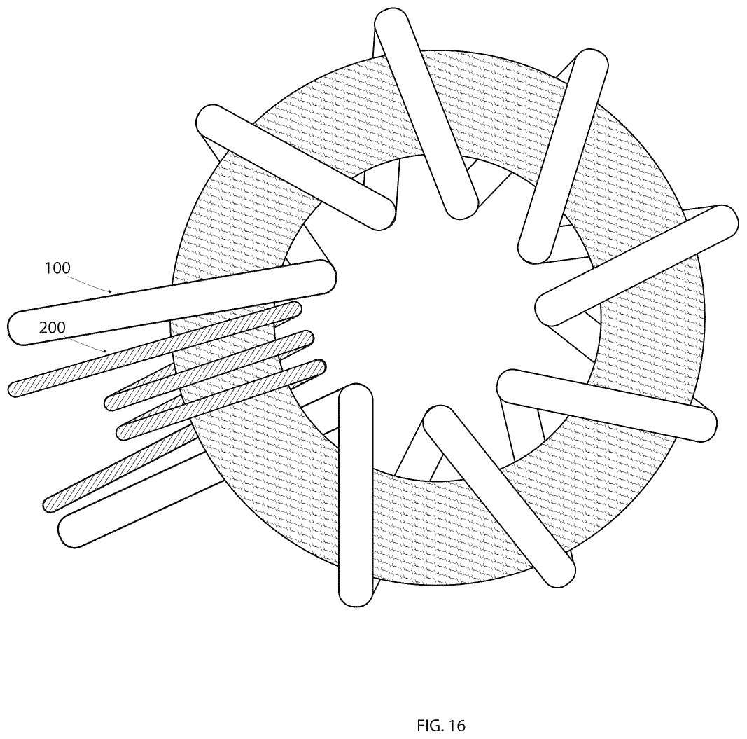

FIG. 15 presents another top view of a toroidal core with the primary coil 100 and the secondary coil 200. In this configuration, the primary coil 100 may be shown wound multiple times around the toroidal core in a circular pattern. The secondary coil 200 may be positioned between two windings of the primary coil 100. The secondary coil 200 may make a single loop around the toroidal core, intersecting with the path of the primary coil 100.

The arrangement in FIG. 15 may demonstrate how the secondary coil 200 can be integrated between the windings of the primary coil 100 while maintaining the overall circular winding pattern around the toroidal core. The primary coil 100 may continue the circular winding pattern before and after the intersection point with the secondary coil 200.

FIG. 16 illustrates an alternative configuration of a toroidal core with the primary coil 100 and the secondary coil 200. In this arrangement, the primary coil 100 may be wound multiple times around the toroidal core in a circular pattern. The secondary coil 200 may be positioned between windings of the primary coil 100. The secondary coil 200 may comprise several loops that may be interspersed between the windings of the primary coil 100.

The configuration shown in FIG. 16 may demonstrate how the secondary coil 200 may be integrated within the structure formed by the primary coil 100 around the toroidal core. This arrangement may allow the primary coil 100 and secondary coil 200 to share the same core while maintaining their separate winding patterns.

In some cases, the toroidal core configuration may offer advantages such as reduced electromagnetic interference and improved flux containment due to the closed magnetic path. The circular geometry of the toroidal core may also allow for efficient use of space in certain applications.

The core-type and toroidal configurations presented in FIGS. 12-16 may provide various options for implementing the current sensing transformer. The choice of configuration may depend on factors such as the desired flux distribution, spatial constraints, and specific application requirements.

One of the primary benefits of combining the sensing coils with the primary coils as presented herein is the ease of forming the current sensing transformer. When plating an inductor, a secondary coil may be plated simultaneously (as well as before or after the primary coil). Because the secondary coil is generally shorter and thinner than the primary coil, as well as being the same material as the primary coil, it does not add a significant material cost to the formation of the inductor.

The use of hybrid materials opens up the ability to effectively place a secondary coil anywhere on the inductor and still get the necessary performance for an accurate sensor. These materials reduce eddy current-based losses to effectively allow the component they are integrated into to shrink or handle higher-frequency applications. The hybrid materials can replace thicker solutions such as Litz wires or laminated layers, which are also much more expensive.

Thus, in an exemplary embodiment, the secondary coil is a hybrid material. In another embodiment, the secondary coil, the primary coil, the core, or a combination of the three is a hybrid material. This may form a hybrid material current sensing transformer.

When the primary coil, the secondary coil, and the core are all a hybrid material, the current sensing transformer may be significantly smaller than other current sensing transformers as each component made with a hybrid material may be significantly smaller than a bulk material or laminated material. This reduces the cost of forming the hybrid material component when compared to the bulk material component, even though the hybrid material contains an insulation layering step.

It will be appreciated if the hybrid current sensing transformers help solve the size and cost issues facing current sensing transformers today in AC systems. As a result, these transformers presented herein may be used to help the manufacturer sense flux in their cores, a designer help determine the current flowing in his system, and even the device manufacturer build smaller systems that rely on current sensing.

These current sense transformers can be used to create an AC and DC current sense system that is very sensitive to inductances generated across a wide range of currents. These systems provide a non-hall effect method of current sense, do not require a separate die, and are lower cost and likely low power than hall effect sensors in general.

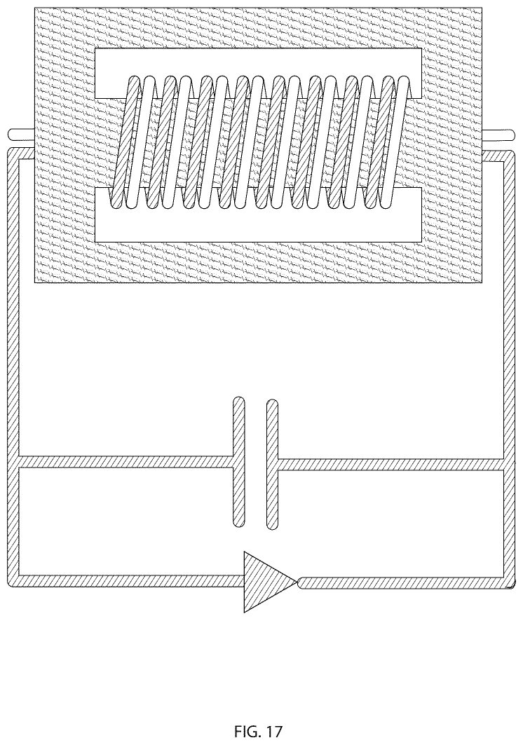

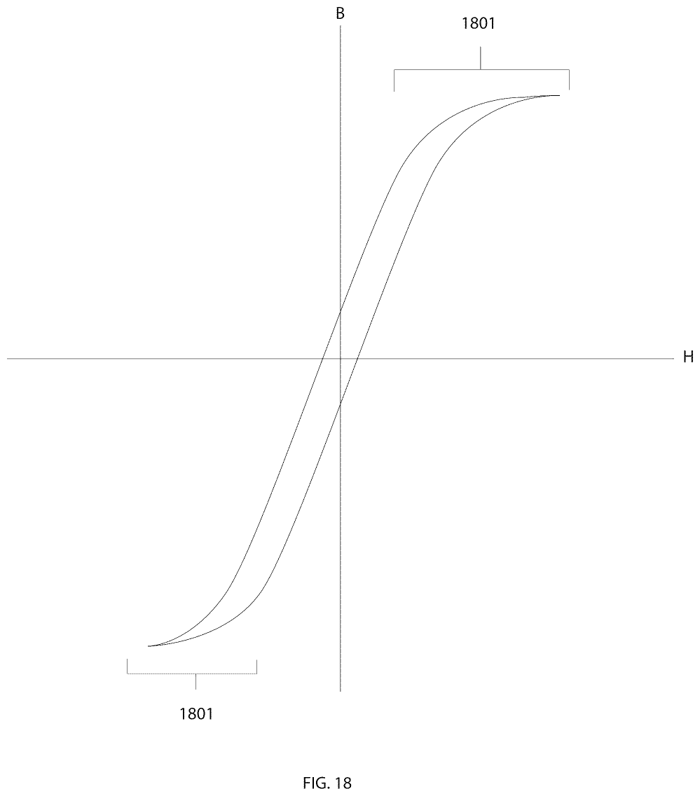

To achieve this, an LC tank circuit may attached to a current sense transformer of the present invention; an example is shown in FIG. 17. This current sense transformer will be able to handle both AC and DC current sense through the addition of this circuit. This works as the current sense of the present invention translates frequency into inductance, and the LC Tank circuit turns direct current into an alternating current-thus allowing the direct current to be measured by the current sense.

The current sense of FIG. 17 may have a B-H curve, as shown in FIG. 18. The addition of an LC Tank circuit will allow for accurate, current sense in regions 1801 and 1802 as inductance changes. However, regions 1801 and 1802 do not cover the current spectrum. When the current falls out of these regions, the inductance does not change as it does in the less permeable regions near saturation.

To improve the performance of a current sense, one would want to remove as much of the region of low inductance change as possible and increase the regions of high inductance change. So, the current sense is sensitive to a broader range of currents, and it is able to measure them with accuracy.

Hybrid materials can be produced with very high permeability, allowing for a steep B-H curve and thus reducing the current levels that experience low inductance change. However, this does not significantly affect regions 1801 and 1802 of the B-H curve.

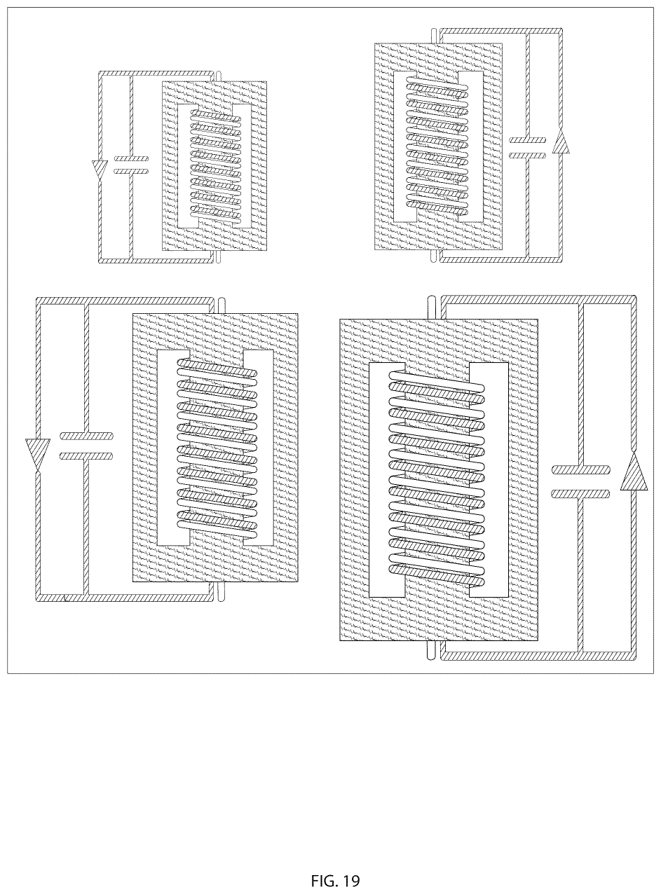

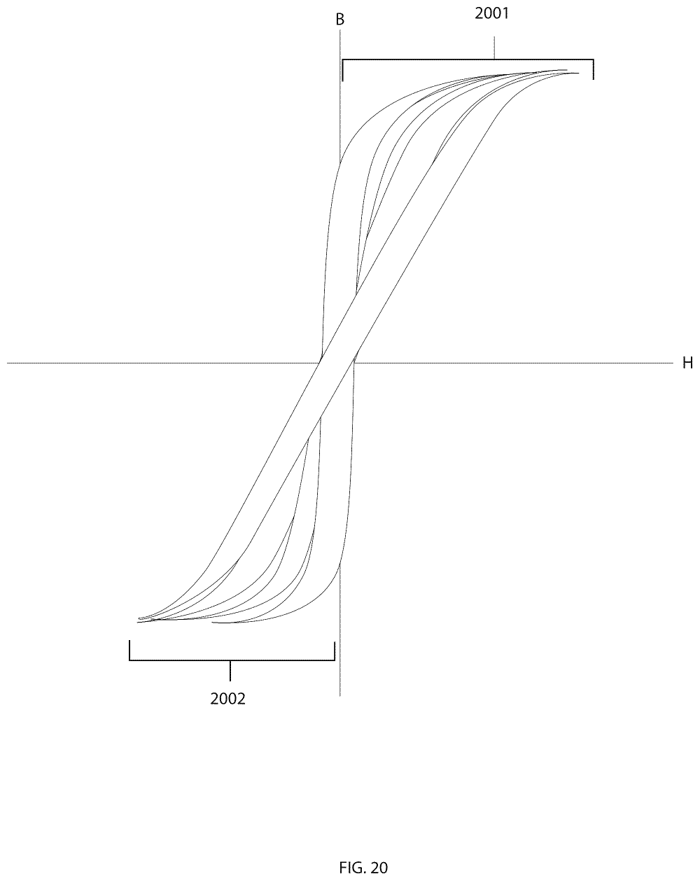

The benefits of hybrid materials is twofold: not only do they produce steep curves, but they also produces small components compatible with semiconductor packaging. Here we can use this fact to build, in at least one embodiment, several of the current senses from FIG. 16, (and this is shown in FIG. 18, where they all can fit on a single die.) It is worth pointing out that these current senses, as shown in FIG. 19 all have cores of different sizes from each other. Since permeability is a function of area, these cores will saturate at different current levels than each other. These cores may be connected by their primary wires.

The result is that the 1801 and 1802 regions for each B-H curve will effectively form a continuous region in the area optimal for inductance change. The result is shown in FIG. 20. Here, we can see several steep B-H curves have come together to form continuous or near continuous regions 2001 and 2002 respectively. Because hybrid material is being used, the current sense system is low-cost, small, and compatible with standard semiconductor packaging, which allows the system to exist on a single die. A traditional laminate material would be too large and too expensive to create this system and find any market for it. However, this present invention opens up the door to this cost and space-saving technique.

The hybrid cores can be replaced with hybrid flux concentrators. In some implementations, the high permeability of the magnetic cores may enhance the magnetic field strength in the vicinity of the hall effect sensors, potentially improving their sensitivity and accuracy. These concentrators can be embedded in a semiconductor substrate and utilized as part of a hall effect sensor. Because they are high frequency and high Bsat, they allow the concentrator to shrink in size, and because they are electroplated, they are compatible with a variety of substrates. The result is small, low-cost, high-performance hall effect sensors. The concentrators can be used in both single and differential hall effect sensors.

Thus there may be three current sense modes: (i) an AC current sense using a transformer with a substrate layered magnetic core, which has provides a high permeability core with excellent signal-to-noise ratio and a high-frequency material for more accurate current sense; (ii) an AC and DC current sense based on the core saturation parameters that provides a Non-hall effect method of current sense compatible with a substrate and does not require separate die resulting in lower cost and likely low power required when compared to hall effect sensors; and (iii) an AD and DC current sense that uses a substrate-layered magnetic core as a flux concentrator resulting in a very small, low cost, substrate compatible hall effect sensor.

These fundamentals result in several components including: A current sense (wire wound) that is fully integrated into a semiconductor substrate with a carrying conductor and a current sense (wire wound) that is integrated as part of a magnetic component such as an inductor/transformer/coupled inductor. When utilized with an electroplated hybrid magnetic material as the core for both the magnetic component and current sense, it results in accurate high-frequency performance.

They also result in both high frequency and high Bsat AC+DC current sense when more hybrid magnetic material is added as a flux concentrator and a hall effect sensor is put in that flux path.

The integration of multiple current sensing transformers with different core sizes on a single die, combined with the use of the magnetic cores as flux concentrators, may provide a versatile and compact solution for current sensing across a wide range of applications. This arrangement may allow for accurate current measurement over various current ranges while maintaining a small form factor suitable for integration into semiconductor packaging.

A number of implementations have been described. Nevertheless, it will be understood that various modifications may be made without departing from the spirit and scope of the disclosure. Accordingly, other implementations are within the scope of the following claims.

1. A current sensing transformer, comprising:
a primary coil;
a secondary coil; and
a substrate-layered magnetic core,
wherein the primary coil and the secondary coil are operably positioned in relation to the substrate-layered magnetic core, and at least one of the primary coil or the secondary coil incorporates a hybrid material.

2. The current sensing transformer of claim 1, wherein the secondary coil is positioned between two or more coils of the primary coil.

3. The current sensing transformer of claim 1, wherein the secondary coil is wound around the core in relation to the primary coil to form a double helix for a length of the core.

4. The current sensing transformer of claim 1, wherein the core is of a hybrid material at least in part.

5. The current sensing transformer of claim 1, wherein a ratio of primary coil windings to secondary coil windings is greater than 1.

6. The current sensing transformer of claim 1, wherein the secondary coil comprises a single winding.

7. The current sensing transformer of claim 1, wherein the current sensing transformer is integrated into semiconductor packaging.

8. The current sensing transformer of claim 1, wherein the core serves as a flux concentrator for a hall effect sensor.

9. The current sensing transformer of claim 1, further comprising an LC tank circuit electrically connected to the secondary coil.

10. The current sensing transformer of claim 9, wherein the LC tank circuit enables sensing of both AC and DC currents.

11. A method of forming a current sensing transformer, comprising:
forming a primary coil;
forming a secondary coil;
forming a substrate-layered magnetic core; and
operably positioning the primary coil and the secondary coil in relation to the substrate-layered magnetic core.

12. The method of claim 11, wherein the secondary coil is wound around a leg of the magnetic core which is not occupied by the primary current.

13. The method of claim 11, wherein the secondary coil is positioned between two or more coils of the primary coil.

14. The method of claim 11, wherein the secondary coil is positioned between two or more coils of the primary coil.

15. The method of claim 11, wherein the secondary coil is wound around the core in relation to the primary coil, forms a double helix for the length of the core.

16. The method of claim 11, wherein the core is of a hybrid material at least in part.

17. The method of claim 11, wherein a ratio of the primary coils to the secondary coils is greater than 1.

18. The method of claim 11, wherein forming the secondary coil comprises forming a single winding.

19. The method of claim 11, further comprising integrating the current sensing transformer into semiconductor packaging.

20. The method of claim 11, further comprising electrically connecting an LC tank circuit to the secondary coil.

21. The method of claim 20, wherein the LC tank circuit enables sensing of both AC and DC currents.
